(19) United States
(12) Patent Application Publication
(10) Pub. No.: US 2006/0087199 A1
(43) Pub. Date: Apr. 27, 2006

(54) Piezoelectric isolating transformer

(76) Inventors: John D. Larson III, Palo Alto, CA (US); Stephen R. Gilbert, San Francisco, CA (US); Ken A. Nishimura, Fremont, CA (US)

Correspondence Address: AGILENT TECHNOLOGIES, INC.;INTELLECTUAL PROPERTY ADMINISTRATION, LEGAL DEPT., P.O. BOX 7599, M/S DL429, LOVELAND, CO, 80537-0599, US

(21) Appl. No.: 10/971,169

(22) Filed: Oct. 22, 2004

(51) Int. Cl. H01L 41/107

(52) U.S. Cl. 310/318

(57) ABSTRACT

The piezoelectric isolating transformer is characterized by an operating frequency range and includes a resonant structure having at least one mechanical resonance in the operating frequency range. The resonant structure has an insulating substrate, a first electro-acoustic transducer and a second electro-acoustic transducer. The substrate has a first major surface and a second major surface opposite the first major surface. The first electro-acoustic transducer is mechanically coupled to the first major surface. The second electro-acoustic transducer is mechanically coupled to the second major surface. One of the transducers is operable to convert input electrical power in the operating frequency range to acoustic energy that excites mechanical vibration in the resonant structure. The other of the transducers converts the mechanical vibration to output electrical power.

### BACKGROUND

Electrical isolating transformers provide electrical isolation between electrical elements. Conventional isolating transformers are based on magnetic coupling, traditionally at line frequency. Isolating transformers that operate at line frequency are big, heavy and are difficult to integrate with the circuit elements between which they provide isolation. More recently isolating transformers that operate at frequencies substantially higher than line frequency have been introduced. This has reduced the size and weight of the isolating transformer, but such isolating transformers remain difficult to integrate with the circuit elements between which they provide isolation.

Low-power electrical isolation has been provided by optical couplers and Micro Electro-Mechanical Systems (MEMS) devices. However, the power transmission capabilities of such devices is limited to a few milliwatts. Moreover, the GaAs optical emitter of an optical coupler is difficult to fabricate on a silicon integrated circuit die.

Accordingly, what is needed is an electrical power isolator capable of providing electrical isolation and capable of transmitting more than a few milliwatts of power. In some applications, what is additionally needed is an electrical power isolator capable of being integrated with the electrical circuits being isolated.

### SUMMARY

The need is met by the invention. In a first embodiment of the invention, a piezoelectric isolating transformer is characterized by an operating frequency range and includes a resonant structure having at least one mechanical resonance in the operating frequency range. The resonant structure includes an insulating substrate, a first electro-acoustic transducer and a second electro-acoustic transducer. The substrate has a first major surface and a second major surface opposite the first major surface. The first electro-acoustic transducer is mechanically coupled to the first major surface. The second electro-acoustic transducer is mechanically coupled to the second major surface. One of the transducers is operable to convert input electrical power in the operating frequency range to acoustic energy that excites mechanical vibration in the resonant structure. The other of the transducers converts the mechanical vibration to output electrical power.

In a second embodiment of the invention, a DC-to-DC converter includes an oscillator, a rectifier, and a piezoelectric isolating transformer. The piezoelectric isolating transformer has an input electrically connected to the oscillator and an output electrically connected to the rectifier. Optionally, the DC-to-DC converter includes a feedback-type regulator that uses an additional piezoelectric isolating transformer. The piezoelectric isolating transformers are typically fabricated on the same substrate.

In a third embodiment of the invention, a fabrication method is disclosed. An insulating substrate is provided. The insulating substrate has a first major surface and a second major surface opposite the first major surface. A first electro-acoustic transducer is formed on the first major surface of the substrate and a second electro-acoustic transducer is formed on the second major surface of the substrate.

Other aspects and advantages of the invention will become apparent from the following detailed description, taken in conjunction with the accompanying drawings, illustrating by way of example the principles of the invention.

### BRIEF DESCRIPTION OF THE DRAWINGS

FIG. 1A illustrates a piezoelectric isolating transformer in accordance with one embodiment of the invention;

FIG. 1B illustrates a circuit adapted to rectify and filter output electrical power from the piezoelectric isolating transformer of FIG. 1A;

FIG. 1C illustrates another embodiment of the piezoelectric isolating transformer that provides full-wave rectification.

FIGS. 2A and 2B illustrate the voltage waveforms exemplary input electrical power to the piezoelectric isolating transformer of FIG. 1A;

FIGS. 3A and 3B illustrate the voltage waveforms of exemplary output electrical power from the piezoelectric isolating transformer of FIG. 1A;

FIGS. 4, 5, and 6 illustrate relationships between operating frequencies and output voltages of the piezoelectric isolating transformer of FIG. 1A;

FIG. 7 illustrates a DC-to-DC converter in accordance with another embodiment of the invention;

FIGS. 8A and 8B illustrate the voltage waveforms of exemplary DC output power from the circuit of FIGS. 1B;

FIG. 9 is a flowchart illustrating a method of fabricating the piezoelectric isolating transformer in accordance with the invention;

FIGS. 10, 11A, 11B, and 11C illustrate additional embodiments of the piezoelectric isolating transformer in accordance with the invention;

FIG. 12 is a top view of a piezoelectric isolating transformer of the invention as it may appear fabricated on an integrated circuit die; and

FIGS. 13A, 13B, 13C and 13D are cross-sectional views of the piezoelectric isolating transformer of FIG. 12 along the section line 13D-13D in FIG. 12.

### DETAILED DESCRIPTION

The invention will now be described with reference to the Figures that illustrate various embodiments of the invention. In the Figures, some sizes of structures or portions may be exaggerated and not to scale relative to sizes of other structures or portions for illustrative purposes and, thus, are provided to illustrate the general structures of the invention. Furthermore, various aspects of the invention are described with reference to a structure or a portion positioned “on” or “above” relative to other structures, portions, or both. Relative terms and phrases such as, for example, “on” or “above” are used herein to describe one structure's or portion's relationship to another structure or portion as illustrated in the Figures. It will be understood that such relative terms encompass different orientations of the device in addition to the orientation depicted in the Figures. For example, if the device in the Figures is turned over, rotated, or both, the structure or the portion described as “on” or “above” other structures or portions would now be oriented “below,” “under,” “left of,” “right of,” “in front of,” or “behind” the other structures or portions. References to a structure or a portion being formed “on” or “above” another structure or portion contemplate that additional structures or portions may intervene. References to a structure or a portion being formed on or above another structure or portion without an intervening structure or portion are described herein as being formed “directly on” or “directly above” the other structure or the other portion. Same reference number refers to the same elements throughout this document.

As shown in the Figures for the purposes of illustration, embodiments of the invention are exemplified by a piezoelectric isolating transformer including a resonant structure characterized by an operating frequency range. The resonant structure has at least one mechanical resonance in the operating frequency range. The resonant structure includes an insulating substrate, a first electro-acoustic transducer and a second electro-acoustic transducer. The substrate has a first major surface and a second major surface opposite the first major surface. The first electro-acoustic transducer is mechanically coupled to the first major surface. The second electro-acoustic transducer is mechanically coupled to the second major surface. One of the electro-acoustic transducers converts input electrical power in the operating frequency range to acoustic energy that excites mechanical vibration in the resonant structure. The other of the transducers converts the mechanical vibration to output electrical power.

The first and the second transducers are electro-acoustic transducers such as piezoelectric electro-acoustic transducers that convert electrical power to acoustic energy and acoustic energy to electrical power. Input electrical power (alternating current (AC) power or pulsed direct current (DC) power) at an operating frequency at or near one of the resonances of the resonant structure applied to the first electro-acoustic transducer is converted by the first electro-acoustic transducer to acoustic energy. The acoustic energy excites the resonant structure to vibrate mechanically at the operating frequency. Continued application of the input electrical power causes a build up of acoustic energy in the resonant structure at the operating frequency. The second electro-acoustic transducer converts the mechanical vibrations of the resonant structure to output electrical power. In this disclosure, the term AC will be understood to encompass pulsed DC.

The operating frequency of the piezoelectric isolating transformer of the invention is on the order of tens or hundreds of Megahertz, substantially higher than the frequencies typically used in power isolating transformers. The high operating frequency allows the piezoelectric isolating transformer to be substantially smaller than any conventional isolating transformer. The piezoelectric isolating transformer can be implemented in a die area of less than one square millimeter or smaller. This is smaller than any existing electrical isolator or transformer device. The piezoelectric isolating transformer is so small that thousands of piezoelectric isolating transformers can be fabricated at a time using known and conventional integrated circuit (IC) fabrication methods. This allows the piezoelectric isolating transformer of the invention to be fabricated in high volume and for a lower cost than the prior art isolators or transformers.

Because of its small size and the compatibility of its fabrication process with existing IC fabrication processing, the piezoelectric isolating transformer of the invention can be fabricated on a chip along with other circuits the piezoelectric isolating transformer is designed to isolate. As for performance, the piezoelectric isolating transformer of the invention provides excellent electrical isolation in a frequency range from DC to about 1 GHz. Applications for the piezoelectric isolating transformer of the invention range widely. For example, the piezoelectric isolating transformer of the invention can be useful in IC chips for telecommunications applications such as Ethernet network adaptors.

In addition, not only does the invention significantly reduce the cost of electrical isolators and transformers, but it also enables new applications for isolators and transformers, including on-chip isolation of high-speed digital and analog circuits. Moreover, the new applications, for example, can involve electrical power isolation in relatively high-power environments such as in medical applications where isolation of electrical power from one circuit to another may prove to be critical in life support systems.

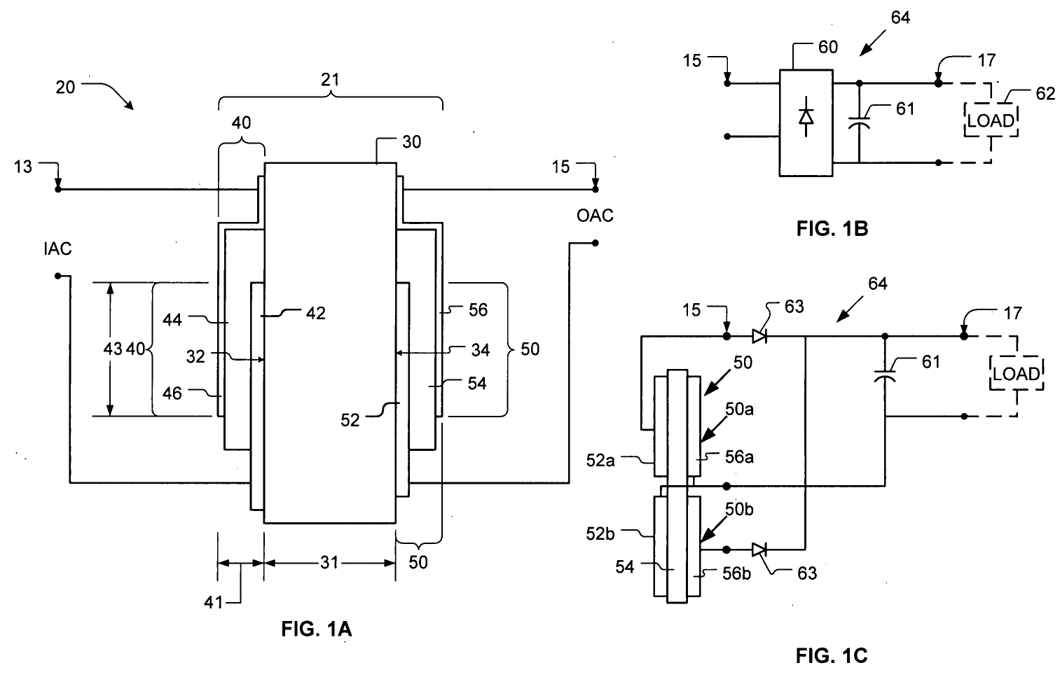

FIG. 1A illustrates a piezoelectric isolating transformer 20 in accordance with one embodiment of the invention. Referring to FIG. 1A, the piezoelectric isolating transformer 20 is implemented as a resonant structure 21 having at least one mechanical resonance in an operating frequency range. In typical embodiments, the center frequency of the operating frequency range is in the range from about 20 MHz to about 500 MHz. The center frequency of the operating frequency range of the exemplary embodiment described herein is about 200 MHz.

The resonant structure 21 is composed of an insulating substrate 30, a first electro-acoustic transducer 40 and a second electro-acoustic transducer 50. The substrate 30 has a first major surface 32 and a second major surface 34 opposite the first major surface 32. The first electro-acoustic transducer 40 is mechanically coupled to the first major surface 32 of the substrate 30. The second electro-acoustic transducer 50 is mechanically coupled to the second major surface 34 of the substrate 30.

The material of substrate 30 is high-resistivity silicon, alumina, glass, ceramic, sapphire or one or more of any number of electrically-insulating materials. Alternatively, the substrate is composed of an at least partially electrically-conducting material and at least one insulating layer. The insulating substrate or the insulating layer electrically insulates the first electro-acoustic transducer 40 from the second electro-acoustic transducer 50 and makes the piezoelectric isolating transformer 20 electrically isolating.

The electro-acoustic transducers 40 and 50 are, for example, thin-film electro-acoustic transducers. Each of the transducers 40 and 50 is operable to convert input AC electrical power to acoustic energy and to convert acoustic energy to output AC electrical power.

The resonant structure 21, including the substrate 30 and the electro-acoustic transducers 40 and 50, is structured to resonate mechanically at least one resonant frequency in the operating frequency range. Typically, the resonant structure 21 has more than one resonant frequency in the operating frequency range.

In the illustrated embodiment, the first electro-acoustic transducer 40 is a thin-film electro-acoustic transducer and has a bottom electrode 42, a piezoelectric layer 44, and a top electrode 46. The electrodes 42 and 44 sandwich the piezoelectric layer 44 and are made of electrically-conducting materials; for example, gold (Au) or platinum (Pt). The electrodes 42 and 44 are electrically connected to the AC input terminals 13 of the piezoelectric isolating transformer 20. The material of piezoelectric layer 44 is any suitable piezoelectric material; for example, lead zirconium titanate Pb(Zr,Ti)O₃ (PZT). The dimensions and total mass of the first electro-acoustic transducer 40, for example its thickness 41, depend on factors such as the operating frequency.

The second electro-acoustic transducer 50 is a thin-film electro-acoustic transducer and has a bottom electrode 52, a piezoelectric layer 54, and a top electrode 56. The electrodes 52 and 54 sandwich the piezoelectric layer 54 and are made of electrically-conducting materials; for example, gold (Au) or platinum (Pt). The electrodes 52 and 54 are electrically connected to the AC output terminals 15 of the piezoelectric isolating transformer 20. The material of piezoelectric layer 54 is any suitable piezoelectric material; for example, lead zirconium titanate Pb(Zr,Ti)O₃ (PZT). The dimensions and total mass of the second electro-acoustic transducer 50, for example its thickness, depend on factors such as the operating frequency.

The first and second electro-acoustic transducers 40 and 50 are typically structured to have a mechanical resonance at a frequency nominally equal to the operating frequency. However, as will be described in more detail below with reference to FIG. 4, the mechanical resonances of the electro-acoustic transducers are substantially lower in Q than the resonances of the resonant structure 21. Specifically, the thickness 41 of the first electro-acoustic transducer 40 is an integral multiple of one-half the wavelength in the electro-acoustic transducer of an acoustic wave nominally equal in frequency to the operating frequency. Since the piezoelectric layer 44 accounts for most of the thickness 41 of the first electro-acoustic transducer, the thickness 41 can be approximated as follows: The speed of sound in PZT is approximately 4,500 meters per second. At an operating frequency of 206 MHz, the wavelength of an acoustic wave in the first electro-acoustic transducer is approximately 22 micrometers, calculated as follows:
(4.5×10³ meters per second)/(2.06×10⁸)

To achieve a thickness that is an integral multiple of one-half the wavelength in the electro-acoustic transducer of an acoustic wave nominally equal in frequency to the operating frequency, the first electro-acoustic transducer 40 is fabricated with the thickness 41 of, for example, 22 micrometers. Typically, the thickness 41 of the first electro-acoustic transducer 40 is, for example, approximately 10 to 20 micrometers (μm). Lateral dimensions 43 of the first electro-acoustic transducer 40 are in the range from a few hundred micrometers to a few thousand micrometers, for example, 300 μm to 3,000 μm. The second electro-acoustic transducer 50 is similar in structure.

Input AC electrical power IAC at the operating frequency is applied to the AC input terminals 13. The first electro-acoustic transducer 40 converts the input AC power IAC to acoustic energy, i.e., mechanical vibrations. The acoustic energy causes the resonant structure 21 to vibrate mechanically at the operating frequency. The frequency of the input AC power IAC is at or near the frequency of one of the resonances of the resonant structure 21.

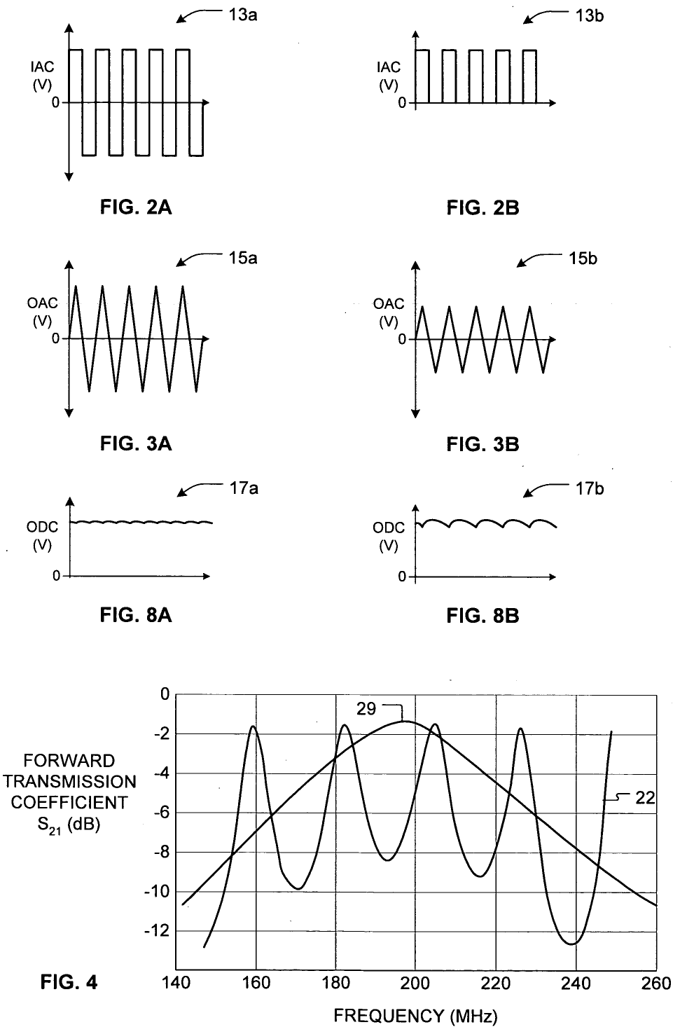

FIG. 2A illustrates one possible voltage waveform 13a of input AC power IAC shown in FIG. 1A. Voltage waveform 13a is a bipolar square wave alternating at the operating frequency; for example, 206 MHz. Alternatively, the input AC power IAC shown in FIG. 1A can be pulsed DC power whose voltage waveform 13b illustrated in FIG. 2B is a unipolar square wave alternating at the operating frequency. For convenience, in this document, the term AC refers to and includes both bipolar AC, for example, the AC voltage waveform 13a, as well unipolar pulsed DC, for example, the pulsed DC voltage waveform 13b.

Referring again to FIG. 1A, the acoustic energy generated by the first electro-acoustic transducer 40 in response to the input AC power IAC causes the resonant structure 21 to resonate at the operating frequency. While the substrate 30, the first electro-acoustic transducer 40, and the second electro-acoustic transducer 50 collectively determine the resonant frequencies of the resonant structure 21, the resonant frequencies are primarily determined by the thickness of the substrate 30 and the speed of sound in the material of the substrate. Accordingly, the thickness and material of the substrate primarily determine the frequencies of the mechanical resonances of resonant structure 21. The operating frequency is chosen to be nominally equal to one of the resonant frequencies. For example, thickness 31 of the substrate 30 is an integral multiple of one-half of the wavelength in the substrate of an acoustic wave nominally equal in frequency to the operating frequency. The speed of sound in silicon is approximately 8,500 meters per second. At the operating frequency of 206 MHz, the wavelength in the substrate 30 of an acoustic wave having a frequency nominally equal to the operating frequency is approximately 41 micrometers, calculated as follows:
(8.5×10³ meters per second)/(2.06×10⁸)

Accordingly, the substrate 30 having a thickness 31 that is an integral multiple of (41/2) micrometers, e.g., 164 micrometers (eight half wavelengths). Typically, the substrate 30 has thickness 31 in the order of one hundred micrometers.

The acoustic energy from the first electro-acoustic transducer 40 causes the resonant structure 21 to resonate, i.e., to vibrate mechanically. Further, continued application of the input AC power IAC to the first electro-acoustic transducer 40 causes acoustic energy at the operating frequency to accumulate within the resonant structure 21. The mechanical vibrations of the resonant structure 21 excite the second electro-acoustic transducer 50. The second electro-acoustic transducer 50 converts the mechanical vibrations into output AC electrical power OAC delivered at the output terminals 15.

FIG. 3A illustrates the voltage waveform 15a of output AC power OAC generated by the second electro-acoustic transducer 50 in response to the bipolar input AC voltage waveform 13a shown in FIG. 2A. FIG. 3B illustrates the voltage waveform 15b of the output AC power OAC generated by the second electro-acoustic transducer 50 in response to the pulsed DC voltage waveform 13b shown in FIG. 2B. The output AC voltage waveforms 15a and 15b of FIGS. 3A and 3B have the same frequency as the input AC voltage waveforms 13a and 13b shown in FIGS. 2A and 2B, respectively.

The output AC power OAC generated by the piezoelectric isolating transformer 20 depends on various factors including the frequency of the input AC power IAC relative to the resonant frequency of the resonant mechanical structure 21. This is because the piezoelectric isolating transformer 20 transforms the input AC power to the output AC power via mechanical resonance of its resonant structure 21.

Referring now to FIG. 4 and additionally to FIG. 1A, curve 22 illustrates how the calculated forward transmission coefficient S₂₁ of a typical embodiment of the piezoelectric isolating transformer 20 depends on frequency over an exemplary frequency range from 140 MHz to 260 MHz. The forward transmission coefficient S₂₁ of the piezoelectric isolating transformer 20 is the ratio of the output AC power OAC output by the second electro-acoustic transducer 50 to the input AC power IAC applied to the first electro-acoustic transducer 40. In calculating the calculated forward transmission coefficient of the piezoelectric isolating transformer 20, the forward transmission coefficients S₂₁ of the first and second electro-acoustic transducers 40 and 50 were assumed to remain constant over the indicated frequency range to enable curve 22 to show the frequency dependence of the resonances of the resonant mechanical structure 21. Due to the multiple mechanical resonances of the resonant mechanical structure 21, the forward transmission coefficient indicated by curve 22 is greater at certain operating frequencies, such as 206 MHz, than at other operating frequencies, such as 215 MHz. The forward transmission coefficient has a peak at the resonant frequencies of the resonant mechanical structure 21. Because the forward transmission coefficient indicated by curve 22 has peaks at multiple frequencies, the piezoelectric isolating transformer 20 is said to have multi-mode operating characteristic.

FIG. 4 also shows curve 29, which illustrates how the calculated forward transmission coefficient S₂₁ of a typical embodiment of the first electro-acoustic transducer 40 varies with frequency. Second electro-acoustic transducer 50 has a similar forward transmission coefficient characteristic. The calculated forward transmission coefficient of the first electro-acoustic transducer 40 is the ratio of the acoustic power generated by first electro-acoustic transducer 40 to the input AC power IAC applied to the first electro-acoustic transducer 40. The forward transmission coefficient frequency characteristic of the first electro-acoustic transducer is typical of a resonant device having a Q substantially lower than the Q of the resonances of resonant mechanical structure 21. This allows the operating frequency to be varied over a frequency range, e.g., from 206 MHz to 215 MHz, that causes a substantial change in the forward transmission coefficient of piezoelectric isolating transformer 20 but that causes little variation in the forward transmission coefficients of the electro-acoustic transducers 40 and 50.

Referring again to FIGS. 1A and 1B, FIG. 1B shows an optional rectifying and smoothing circuit 64 that forms part of some embodiments of the piezoelectric isolating transformer 20. The rectifying and smoothing circuit 64 is connected to the AC output terminals 15 to convert the output AC power OAC output by the second electro-acoustic transducer 50 to output DC power ODC. Rectifying and smoothing circuit 64 is composed of a rectifier 60 and a filter capacitor 61. In an embodiment, the rectifier 60 is a single diode rectifier that produces half-wave rectification. In another embodiment, the rectifier 60 is a bridge rectifier that provides full-wave rectification. The bridge rectifier is composed of four diodes. The rectifying and smoothing circuit 64 delivers the output DC power ODC to DC output terminals 17. FIG. 1B shows a load 62 connected to the DC output terminals 17. The load 62 may be a resistor but is more typically a circuit that draws DC power from the piezoelectric isolating transformer 20.

In another embodiment, the second electro-acoustic transducer 50 is divided into two sub-transducers 50a and 50b as shown in FIG. 1C. Sub-transducers 50a and 50b are mechanically coupled to the first major surface 32 of the substrate 30 in a manner similar to that shown in FIG. 1A. Sub-transducers 50a and 50b share a common piezoelectric element 54, but have respective electrodes 52a, 56a and 52b and 56b. The sub-transducers 50a and 50b are electrically connected in series so that they produce anti-phase voltages. This enables the embodiments shown in FIG. 1C to provide full-wave rectification with only two diodes. The series connection is made by connecting the electrode 52b of the sub-transducer 50b to the electrode 56a of the sub-transducer 50a. The connection between the electrodes 52b and 56a is connected via one of the AC output terminals 15 to one side of the capacitor 61. The electrode 52a of the sub-transducer 50a and the electrode 56b of the sub-transducer 50b are each connected via a respective AC output terminals 15 and a diode 63 to the other side of the capacitor 61.

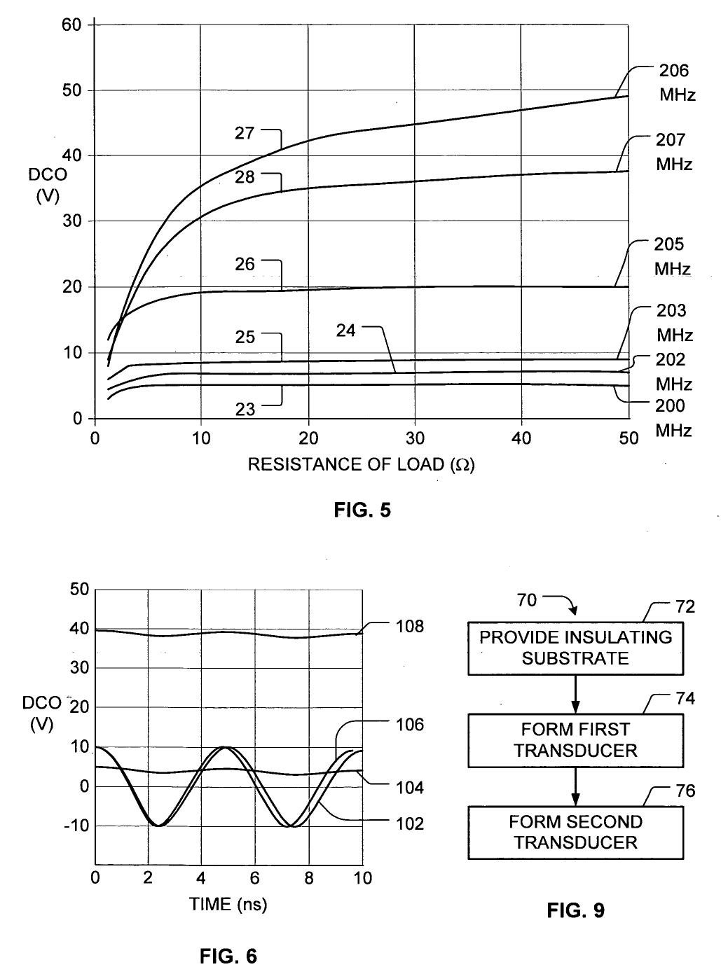

FIG. 5 is a graph illustrating the dependence of the output DC voltage delivered by an embodiment of the piezoelectric isolating transformer 20 incorporating the rectifying and smoothing circuit 64 on the resistance of load 62 at various operating frequencies. Referring to FIGS. 1A, 1B, and 5, curves 23, 24, 25, 26, 27, and 28 show the dependence of the output DC voltage on the resistance of the load 62 at operating frequencies of 200 MHz, 202 MHz, 203 MHz, 205 MHz, 206 MHz, and 207 MHz, respectively. In the example shown, the resistance of the load 62 ranges from approximately two ohms to approximately 50 ohms. In the example illustrated in FIG. 5, the output DC voltage is highest at an operating frequency of 206 MHz. This operating frequency corresponds to the resonance peak at 206 MHz shown in FIG. 4.

FIG. 6 shows the relationship between the operating frequency and the output DC voltage in a different way. Curve 102 represents the voltage waveform of input AC electrical power IAC. The voltage alternates sinusoidally at a frequency of 200 MHz between peaks of +10 V and −10 V. The input AC power of frequency 200 MHz results in an output DC power ODC having a voltage of approximately 5 V DC. The voltage waveform of the output DC power is represented by curve 104. FIG. 6 shows the effect of changing the frequency of the input AC power 106 from 200 MHz to 206 MHz without changing the voltage of the input AC power IAC or the resistance of the load 62. The voltage waveform of the input AC power is represented by curve 106. The input AC power of frequency 206 MHz results in output DC power having a voltage of almost 40 V. The voltage waveform of the output DC power is represented by curve 108. Thus, piezoelectric isolating transformer 20 is capable of delivering approximately eight times the DC voltage when the operating frequency is 206 MHz than when the operating frequency is 200 MHz. This is consistent with graphs illustrated in FIGS. 4 and 5.

FIGS. 4, 5, and 6 show that the ratio of the output DC electrical power ODC to the input electrical power IAC of the piezoelectric isolating transformer 20 shown in FIG. 1A depends strongly on the relationship between the operating frequency, i.e., the frequency of input AC power IAC, and the resonant frequency of the resonant structure 21 of the piezoelectric isolating transformer 20.

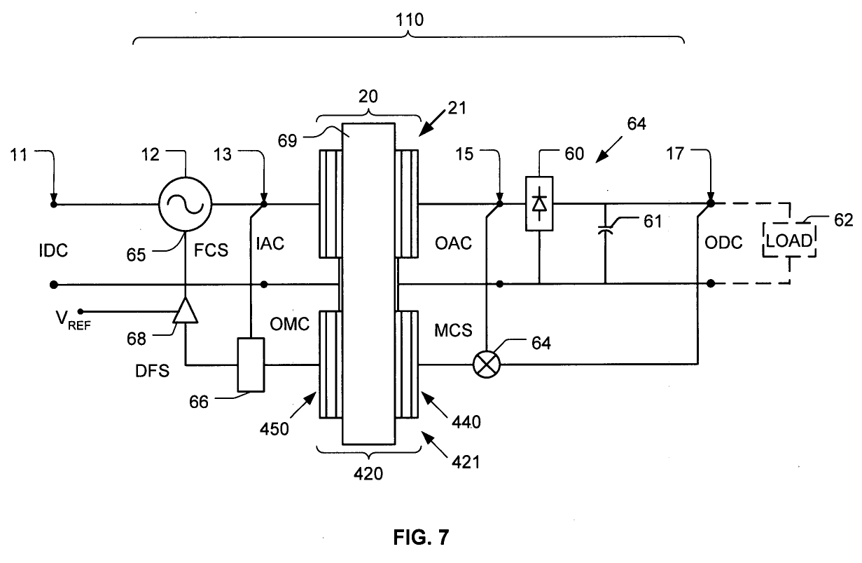

FIG. 7 is a block diagram of an exemplary embodiment 110 of a DC-to-DC converter in accordance with the invention. The DC-to-DC converter 110 incorporates an embodiment of the piezoelectric isolating transformer 20 described above with reference to FIG. 1A. Referring to FIGS. 1A, 1B, and 7, the DC-to-DC converter 110 is composed of an oscillator 12, the piezoelectric isolating transformer 20, and the rectifier 60. The oscillator 12 is connected to the AC input terminals 13 of the piezoelectric isolating transformer 20. The rectifier 60 is connected to the AC output terminals 15 of piezoelectric isolating transformer 20.

In the example shown in FIG. 7, the rectifier 60 is part of a rectifying and smoothing circuit 64. The oscillator 12 converts input DC power IDC received at the DC input terminals 11 to input AC power IAC and feeds the input AC power IAC to the AC input terminals 13 of the piezoelectric isolating transformer 20. The frequency of the input AC power IAC is in the operating frequency range of the piezoelectric isolating transformer 20. The piezoelectric isolating transformer 20 converts the input AC power IAC received from the oscillator 12 to output AC power OAC, as described above, and delivers the output AC power to the AC output terminals 15. The rectifier 60 receives the output AC power OAC from the output terminals 15 of the piezoelectric isolating transformer 20 and rectifies the output AC power to provide raw DC power. In the example shown, the rectifying and smoothing circuit 64 is composed of the rectifier 60 and the filter capacitor 61, and the filter capacitor 61 filters the raw DC power to provide the output DC power ODC at the DC output terminals 17. FIG. 7 shows the load 62 connected to the DC output terminals 17.

The capacitance of filter capacitor 61 is typically small since the RC time constant of the capacitance of the filter capacitor 61 and the minimum anticipated resistance of the load 62 need only be greater than approximately four nanoseconds (approximately one period at 206 MHz). For example, in an embodiment that delivers an output DC voltage of 10 V at a maximum current of 1 A, the minimum load resistance is 10 Ω. In such embodiment, the capacitance of the capacitor 61 is about one nanofarad. This is significantly less than the tens or hundreds of microfarad capacitors used in power supplies operating at lower frequencies. The value of the filter capacitor 61 and the type of diodes of the rectifier 60 can vary widely, depending on the implementation and the operating frequency.

FIGS. 8A and 8B illustrate exemplary voltage waveforms of the output DC power ODC. FIG. 8A shows the voltage waveform 17a of the output DC power ODC generated by an embodiment the rectifying and smoothing circuit 64 that provides full-wave rectification in response to the voltage waveform 15a of the output AC power OAC shown in FIG. 3A. FIG. 8B shows the voltage waveform 17b of the output DC power ODC generated by an embodiment the rectifying and smoothing circuit 64 that provides half-wave rectification in response to the voltage waveform 15a of the output AC power OAC shown in FIG. 3B. The filter capacitor 61 has the same capacitance in the examples shown in FIGS. 8A and 8B.

As illustrated by FIGS. 4, 5, and 6 and discussed above, the voltage of the output DC power ODC delivered by piezoelectric isolating transformer 20 is sensitive to the frequency of the input AC power IAC generated by the frequency-controlled oscillator 12 relative to the resonant frequency of the resonant mechanical structure 21 (FIG. 1A) and to the current drawn by the load. In some embodiments of the DC-to-DC converter 110, the oscillator 12 is a fixed-frequency oscillator, and the DC-to-DC converter additionally includes a conventional DC regulator (not shown) interposed between the DC output terminals 17 and the load 62. The DC regulator operates to provide a constant voltage to the load 62 notwithstanding variations in one or more of the frequency of the input AC power, the resonant frequency of the resonant mechanical structure 21 due to temperature variations, etc., and the load current.

The embodiment of the DC-to-DC converter 110 shown in FIG. 7 includes a feedback control circuit that controls the frequency of the input AC power in a manner that causes the DC-to-DC converter to deliver the output DC power ODC at a constant voltage notwithstanding variations in one or more of the frequency of the input AC power, the resonant frequency of the resonant mechanical structure 21 due to temperature variations, etc., and the load current. In the DC-to-DC converter 110, the oscillator 12 is a frequency-controlled oscillator that includes a frequency control input 65. A frequency control signal FCS applied to the frequency control voltage determines the frequency at which the frequency-controlled oscillator 12 converts the input DC power IDC received at the DC input terminals 11 to input AC power IAC delivered to the AC input terminals 13 of the piezoelectric isolating transformer 20. In addition, the oscillator 12 can include circuitry to monitor the phase relationship between the voltage of the input AC power IAC applied to the first transducer 40 and the current flowing into the first transducer 40 to determine the relative relationship between the operating frequency and the mechanical resonance frequency of the mechanically-resonant system 21.

The above-mentioned feedback loop is connected between the DC output terminals 17 of the DC-to-DC converter 110 and the frequency control input 65 of the frequency-controlled oscillator 12 to provide the frequency control signal FCS. The feedback loop includes a modulator 64, a feedback piezoelectric isolating transformer 420, a demodulator 66 and a comparator 68.

The feedback piezoelectric isolating transformer 420 and the piezoelectric isolating transformer 20 are fabricated on a common substrate 69. The feedback piezoelectric isolating transformer 420 is structurally similar to the piezoelectric isolating transformer 20 and has a resonant structure 421 composed of part of the substrate 69, a first electro-acoustic transducer 440 and a second electro-acoustic transducer 450.

The modulator 64 has a modulation input electrically connected to the DC output terminals 17 and a carrier input electrically connected to the AC output terminals 15 of the piezoelectric isolating transformer 20. The modulator 64 additionally has an output electrically connected to the first electro-acoustic transducer 440 of the feedback piezoelectric isolating transformer 420. The AC voltage waveform of the output AC power OAC is received at the carrier input of the modulator 64 from the AC output terminals 15 of the piezoelectric isolating transformer 20 and serves as a carrier signal.

The second electro-acoustic transducer 450 of the feedback piezoelectric isolating transformer 420 is electrically connected to the modulated signal input of the demodulator 66. The demodulator 66 additionally has a carrier input and an output. The carrier input is electrically connected to the input terminals 13 of the piezoelectric isolating transformer 20. The output is connected to one input of the comparator 68. The comparator 68 additionally has a reference input and an output. The reference input is electrically connected to receive a reference voltage V_{REF}. The output is electrically connected to the frequency control input 65 of the frequency-controlled oscillator 12.

In operation, the modulator 64, which may be embodied as a mixer, modulates the carrier signal received from the AC output terminals 15 of the piezoelectric isolating transformer 20 with the DC voltage of the output DC power ODC received from the DC output terminals 17. The modulation is performed in a manner that enables the resulting modulated carrier signal MCS to represent the voltage of the output DC power ODC in a way that can be transmitted through the feedback piezoelectric isolating transformer 420 without significant loss of accuracy. Since the forward transmission function of the feedback piezoelectric isolating transformer 420 depends on the relationship between the operating frequency and the resonant frequency of the resonant mechanical structure that constitutes part of the feedback piezoelectric isolating transformer in the manner depicted by curve 22 shown in FIG. 4, amplitude modulation is not the preferred modulation method, although it may be used. Examples of suitable alternatives are frequency modulation, phase modulation, pulse modulation and digital coding.

The feedback piezoelectric isolating transformer 420 operates similarly to the piezoelectric isolating transformer 20. That is, the feedback piezoelectric isolating transformer 420 receives, at its first electro-acoustic transducer 440, the modulated carrier signal MCS generated by the modulator 64. The first electro-acoustic transducer converts the modulated carrier signal to acoustic energy that excites mechanical vibration in the resonant mechanical structure 421. The modulated carrier signal has the same frequency as the output AC power OAC and the mechanical resonant structure 421 has resonances similar to the resonant mechanical structure 21. Consequently, the modulated carrier signal is in the operating frequency range of the feedback piezoelectric isolating transformer 420. The second electro-acoustic transducer 450 converts part of the mechanical vibration in the resonant structure 421 to an output modulated carrier signal OMC.

The demodulator 66 demodulates the output modulated carrier signal OMC using the signal received at its carrier input from the AC input terminals 13 to produce a demodulated feedback signal DFS. The demodulated feedback signal is a DC level representing the DC voltage at the output terminals 17 of the DC-to-DC converter 110. The comparator 68 compares the demodulated feedback signal DFS with the reference voltage V_{REF} to generate the frequency control signal FCS. The comparator 68 feeds the frequency control signal FCS to the frequency control input 65 of the frequency-controlled oscillator 12.

Consequently, if the DC voltage of the output DC power ODC at the DC output terminals 17 changes, corresponding changes take place in the modulated carrier signal MCS, the output modulated carrier signal OMC and the demodulated feedback signal DFS. The demodulated feedback signal is compared with the reference voltage, which results in a change in the frequency control signal FCS at the frequency control input 65 of the frequency-controlled oscillator 12. At the frequency-controlled oscillator 12, the change in the frequency control signal FCS at the frequency control input 65 resulting from the change in the voltage of the output DC power ODC changes the frequency of the input AC power IAC in a manner that reverses the change in the voltage of the output DC power ODC. This restores the voltage of the output DC power ODC to its original level.

FIG. 9 is a flowchart 70 illustrating a method in accordance with the invention for fabricating a piezoelectric isolating transformer. In block 72, an insulating substrate is provided. The insulating substrate has a first major surface and a second major surface opposite the first major surface. In block 74, a first electro-acoustic transducer is formed on the first major surface of the substrate. In block 76, a second electro-acoustic transducer is formed on the second major surface of the substrate opposite the first electro-acoustic transducer.

In an embodiment of the method shown in FIG. 9 in which an embodiment of piezoelectric isolating transformer 20 shown in FIG. 1A is fabricated, the insulating substrate 30 having the first major surface 32 and the second major surface 34 opposite the first major surface 32 is provided in block 72. The first electro-acoustic transducer 40 is formed on the first major surface 32 of the substrate 30 in block 74. The second electro-acoustic transducer 50 is formed on the second major surface 34 of the substrate 30 opposite the first electro-acoustic transducer 40 in block 76.

The above-described method is typically used to fabricate thousands of piezoelectric isolating transformers at a time on a single wafer. At the end of the processing, the wafer is singulated into individual piezoelectric isolating transformers. This substantially reduces the cost of fabricating each piezoelectric isolating transformer. Additional methods for fabricating an individual piezoelectric isolating transformer are described below on the understanding that they too are typically performed on the wafer scale to fabricate thousands of piezoelectric isolating transformers at a time.

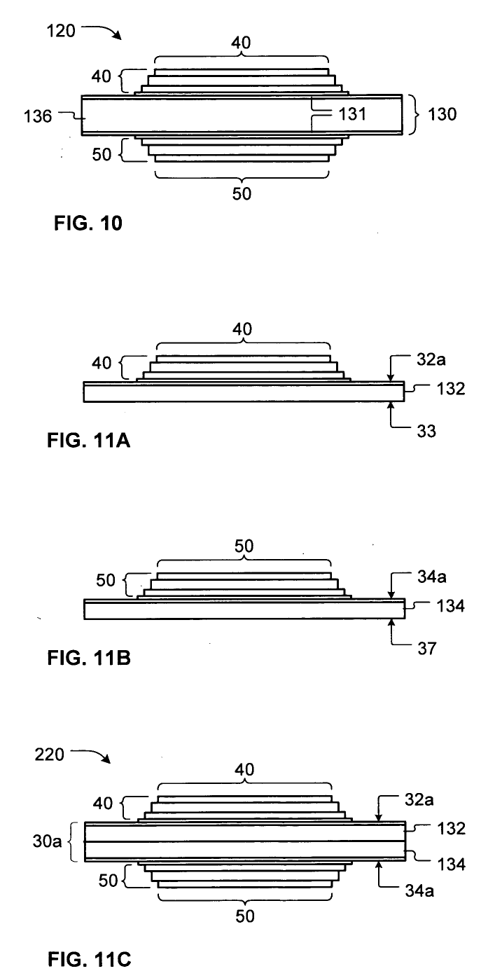

The method for fabricating a piezoelectric isolating transformer illustrated in FIG. 9 can be applied to fabricate piezoelectric isolating transformers differing in structural detail from the piezoelectric isolating transformer 20 shown in FIG. 1A. For example, FIG. 10 illustrates another embodiment of a piezoelectric isolating transformer 120 in accordance with the invention. Elements of the piezoelectric isolating transformer 120 of FIG. 10 that correspond to elements of the piezoelectric isolating transformer 20 of FIG. 1A are assigned similar reference numbers. Referring to FIG. 10, the piezoelectric isolating transformer 120 includes an insulating substrate 130 composed of a base layer 136 of material that is at least partially electrically-conducting. To electrically insulate electro-acoustic transducers 40 and 50 from one another, the substrate 130 also includes a layer 131 of insulating material interposed between each of the electro-acoustic transducers 40 and 50 and base layer 136. Alternatively, the substrate 130 may additionally include a layer 131 of insulating material between only one of the electro-acoustic transducers 40 and 50 and the base layer 136. In a further example (not shown), a layer of insulating material is sandwiched between two layers of at least partially electrically conducting base material and each of the electro-acoustic transducers 40 and 50 is fabricated on a respective one of the base layers. The presence of at the least one layer 131 of insulating material between the electro-acoustic transducers 40 and 50 allows the substrate 130 to be called insulating despite it being composed at least in part of at least partially electrically-conducting material. In another embodiment, the material of the substrate 130 is high-resistivity silicon, alumina, glass, ceramic, sapphire or another suitable electrically-insulating material.

FIGS. 11A, 11B, and 11C show another embodiment 220 of a piezoelectric isolating transformer in accordance with the invention. Elements of the piezoelectric isolating transformer 220 shown in FIGS. 11A, 11B, and 11C that correspond to elements of the isolating transformer 20 shown in FIG. 1A are assigned the same reference numerals and will not be described again here. Analogous but changed portions are assigned the same reference numbers followed by letter “a.”

Referring to FIGS. 11A, 11B, and 11C, the piezoelectric isolating transformer 220 is composed of a first substrate 132 and a second substrate 134. Each substrate has a first major surface and a second major surface opposite the first major surface, i.e., the first substrate 132 has first major surface 32a and a second major surface 33 opposite its first major surface 32a, and the second substrate 134 has a first major surface 34a and a second major surface 37 opposite its first major surface 34a. The first electro-acoustic transducer 40 is located on the first major surface 32a of the first substrate 132. The second electro-acoustic transducer 50 is located on the first major surface 34b of the second substrate 134. The first substrate 132 and the second substrate 134 are joined together with the second major surface 33 juxtaposed with the second major surface 37 and with the first electro-acoustic transducer 40 opposite the second electro-acoustic transducer 50. The first substrate 132 and the second substrate 134 collectively constitute an insulating substrate 30a.

The piezoelectric isolating transformer 220 is fabricated as follows: a first substrate 132 and a second substrate 134 are provided. Each substrate has a first major surface and a second major surface opposite the first major surface as just described. The first electro-acoustic transducer 40 is formed on the first major surface 32a of the first substrate 132. The second electro-acoustic transducer 50 is formed on the first major surface 34b of the second substrate 134. Each electro-acoustic transducer is formed by sequentially depositing and patterning a first electrode layer, a piezoelectric layer and a second electrode layer in a manner similar to that described below. The second major surface 33 of the first substrate 132 is joined to the second major surface 37 of the second substrate 134 with the first electro-acoustic transducer 40 located opposite the second electro-acoustic transducer 50. Joining the first substrate 132 and the second substrate 134 forms the insulating substrate 30a.

In an embodiment, the second major surface 33 of the first substrate 132 and the second major surface 37 of the second substrate 134 are each ground, polished, or otherwise processed to ensure intimate contact between them prior to joining the first substrate 132 and the second substrate 134. Conventional substrate bonding techniques are used to join the substrates 132 and 134.

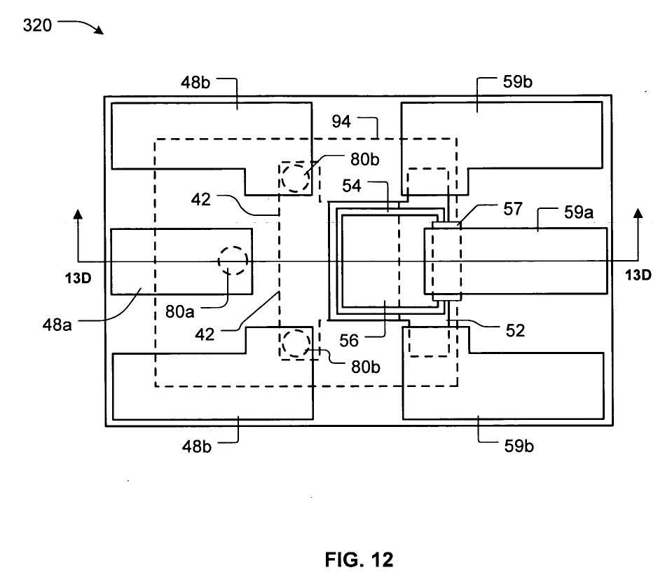

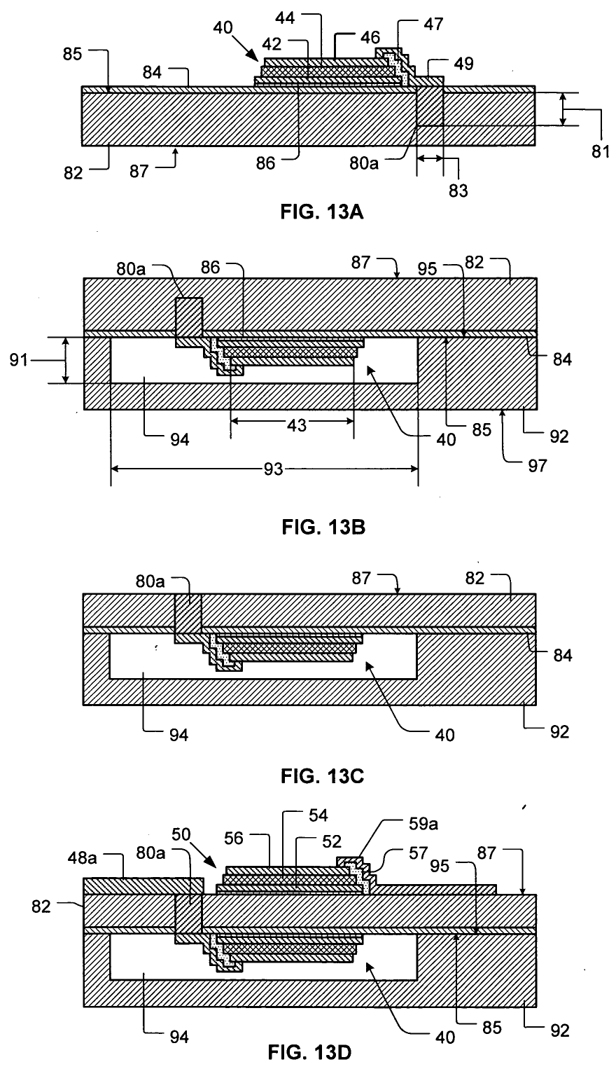

FIG. 12 is a top view of an alternative embodiment 320 of a piezoelectric isolating transformer in accordance with the invention. FIG. 12 is a plan view of the piezoelectric isolating transformer as it may appear fabricated on an integrated circuit die. In FIG. 12, portions of the piezoelectric isolating transformer 320 hidden behind or under other portions are generally not shown; however, selected hidden portions of the piezoelectric isolating transformer 320 are illustrated using broken lines to aid in the description of the piezoelectric isolating transformer 320. FIGS. 13A, 13B, 13C and 13D are cross-sectional views of the piezoelectric isolating transformer 320 at various stages during its fabrication. The cross-sectional views are all taken along section line 13D-13D shown in FIG. 12. In FIGS. 12 and 13A through 13D, additional details of the structure of and method of fabricating a piezoelectric isolating transformer of the invention are illustrated.

The piezoelectric isolating transformer 320 is fabricated in accordance with the process described above with reference to FIG. 9 using known semiconductor fabrication processes, for example, deposition, patterning, and etching. Elements of the piezoelectric isolating transformer 320 shown in FIGS. 12 and 13A through 13D that correspond to elements of the piezoelectric isolating transformer 20 of FIG. 1A are assigned the same reference numerals and will not be described again here.

Referring first to FIGS. 12 and 13D, the piezoelectric isolating transformer 320 is composed of a first substrate 82 and a second substrate 92. The first electro-acoustic transducer 40 and the second electro-acoustic transducer 50 are located opposite one another on the opposed major surfaces 85 and 87, respectively, of the first substrate 82. The second substrate 92 defines a cavity 94 that extends into the second substrate from the major surface 95. The second substrate 92 is bonded to the first substrate 82 with the major surface 95 juxtaposed with the major surface 85 and the first electro-acoustic transducer 40 located in the cavity 94. As will be described in more detail below, the substrates 82 and 92 are bonded together prior to fabrication of the second electro-acoustic transducer 50. Consequently, the second substrate 92 protects the first electro-acoustic transducer 40 during fabrication of the second electro-acoustic transducer 50.

The piezoelectric isolating transformer 320 is fabricated as follows. The first insulating substrate 82 and the second insulating substrate 92 are provided. Each substrate has a first major surface and a second major surface opposite the first major surface. The first electro-acoustic transducer 40 is formed on the first major surface 85 of the first substrate 82. A cavity 94 extending from the first major surface 95 of the second substrate 92 is formed in the second substrate. The first major surface 85 of the first insulating substrate 82 and the first major surface 95 of the second substrate 92 are bonded together with the first transducer 40 located within the cavity 94 in the second substrate 92. After the bonding, the second transducer 50 is formed on the second major surface 87 of the first insulating substrate 82 opposite the first electro-acoustic transducer 40.

Fabrication of the piezoelectric isolating transformer 320 will now be described in more detail with reference to FIGS. 12, and 13A through 13D. Referring first to FIG. 13A, the first substrate 82 having a first major surface 85 and a second major surface 87 opposite the first major surface 85 is provided. The first substrate 82 is, for example, part of a silicon wafer. In another embodiment, the material of the first substrate 82 is high-resistivity silicon, alumina, glass, ceramic, sapphire or another suitable electrically-insulating material. The first substrate 82 constitutes at least part of the insulating substrate of the piezoelectric isolating transformer 320.

The first substrate 82 is oxidized to form an insulating layer 84 of thermal silicon dioxide (SiO₂) with thickness between 100 nm and 10 μm on the major surface 85. The insulating layer 84 can alternatively be deposited by chemical vapor deposition. If needed for additional dielectric isolation, the insulating layer 84 may additionally or alternatively be composed of a 100 nm- to 10 μm-thick layer of a sputter-deposited insulating material such as aluminum oxide (AlOₓ). The major surface of the insulating layer 84 becomes the major surface 85 of the first substrate 82.

Contact vias 80a, 80b that extend into the first substrate 82 from the major surface 85 are then formed. Any number of contact vias can be formed. Reference number 80 is used to generically refer to the contact vias in general, but reference number 80 followed by a letter such as “a” is used to refer to a particular contact via or set of contact vias.

The contact vias 80 are formed by first etching through the insulating layer 84 and then by etching part-way through the substrate 82 using a conventional deep etch process. The vias 80 have a depth 81 that depends on the desired final thickness of the insulating substrate 30 shown in FIG. 1A. In the illustrated example, the vias 80 have a depth 81 of approximately 100 μm and a diameter 83 no less than 10 μm. In an embodiment in which the first substrate 82 is already of the desired final thickness, the contact vias 80 extend through the entire thickness of the first substrate 82. The contact vias 80 are filled with high-conductivity metal, for example, gold (Au), aluminum (Al), copper (Cu), tungsten (W), or platinum (Pt). If necessary, top surfaces of the vias 80 are made co-planar with the major surface 85 using a CMP (chemical mechanical polishing) or etch-back process.

Before fabricating the first electro-acoustic transducer 40 on the first substrate 82, an adhesion layer 86 of, for example, TiAlN (Titanium Aluminum Nitride) is deposited on the major surface 85 of the first substrate 82. The adhesion layer 86 promotes adhesion between the first transducer 40 and the first substrate 82. Further, the adhesion layer 86 serves as an electrically-conducting diffusion barrier between the vias 80 and the bottom electrode 42 of the first transducer 40. This protects the contact vias 80 from damage during the deposition of the piezoelectric layer 44. For the adhesion layer 86, an oxidation-resistant material is preferred because the piezoelectric layer 44 is deposited at a high temperature (for example, 550° C.) in an oxidizing ambient. Other possible materials for the adhesion layer 86 include TaSiN (Tantalum Silicon Nitride), TiN (Titanium Nitride), and TiAl. The adhesion layer 86 has a thickness on the order of tens of nanometers, for example, 50 nm to 100 nm.

The first electro-acoustic transducer 40 is then fabricated on the first major surface 85 of the first substrate 82. The first transducer 40 includes several layers, each of which is deposited in turn and may be etched in turn. However, in the illustrated embodiment, the layers 42, 44, and 46 of the first electro-acoustic transducer 40 are deposited sequentially, then etched in a top-down order. To fabricate the first transducer 40, the bottom electrode 42 is sputter-deposited with a thickness of approximately 100 nm, for example. The material for the bottom electrode 42 is any suitable noble metal, for example, platinum (Pt) or iridium (Ir). For improved series resistance, the bottom electrode is additionally composed of a layer of a suitable high-conductivity metal, for example, gold (Au), sputter deposited with thickness of approximately 1 μm, for example. The above-mentioned layer of the noble metal is deposited on top of the layer of the high-conductivity metal. An extension of the bottom electrode 42 is located above the contact vias 80b shown in FIG. 12 and makes electrical contact with the contact vias 80b.

The piezoelectric layer 44 is a layer of sputter-deposited PZT with thickness in the range from about 1 μm to about 20 μm, for example. Other deposition methods may be used to form the piezoelectric layer 44, including, for example, chemical solution deposition and metal organic chemical vapor deposition. The top electrode 46 is sputter-deposited with thickness of, for example, 100 μm, of again, platinum (Pt) or gold (Au). When Au is used, the top electrode 46 can include a thin top adhesion layer (not shown in the Figures) of chromium (Cr), for example, between the piezoelectric layer 44 and the Au layer.

The top electrode 46 is patterned and etched using a dry etch technique with appropriate etch chemistry. The piezoelectric layer 44 is patterned and etched using a wet etch or dry etch techniques. The bottom electrode 42 and adhesion layer 86 are patterned and etched, again using a dry etch technique. Etching of the bottom electrode 42 and the adhesion layer 86 stops at the insulating layer 84, as well as at the contact via 80a.

For improved series resistance, an Au layer can be added on top of the top electrode 46 using, for example, a lift-off technique. This layer is not shown in the Figures. In one embodiment, the thickness of the top electrode 46 above the piezoelectric layer 44 is identical to the thickness of the bottom electrode 42 below the piezoelectric layer 44. The lateral dimensions of the first transducer 40 depend on the application. In an exemplary embodiment, the lateral dimensions 43 of the first transducer 40 range from approximately 300 μm to approximately 3 mm.

A dielectric layer, such as a layer of SiO₂, is deposited and etched to define a step insulator 47. The step insulator 47 covers part of the piezoelectric layer 44 and the bottom electrode 42 of the first electro-acoustic transducer 40. A layer of a suitable electrically-conducting material such as gold (Au) is then deposited with a typical thickness of a few micrometers; for example, about 1 μm to about 3 μm. The layer is etched to define a conducting trace 49 that extends over the step insulator from the top electrode 46 of the first transducer 40 to the contact via 80a. Overlap between the conducting trace 49 and the first transducer 40 is minimized to minimize the effect of the additional mass of the overlapping portion of the conducting trace 49 on the resonant characteristics of the first transducer 40, the piezoelectric isolating transformer 20, or both.

Referring now to FIGS. 12 and 13B, a second substrate 92 is provided. The second substrate 92 has a first major surface 95 and a second major surface 97 opposite the first major surface 95. Typically, the substrates 82 and 92 are parts of respective silicon wafers, as described above. A cavity 94 is formed in the second substrate 92. The cavity extends into the second substrate 92 from the first major surface 95. The cavity 94 has a depth 91 and lateral dimensions 93 sufficient to accommodate the first electro-acoustic transducer 40 plus respective clearances. Clearances in the range from about 50 μm to about 100 μm are typically sufficient.

The first substrate 82 is next bonded to the second substrate 92 with the first major surface 85 in contact with the first major surface 95 and with the first transducer 40 located in the cavity 94. A standard silicon bonding process is employed to bond the substrates 82 and 92. The result of the bonding is illustrated in FIG. 13B. Bonding the two substrates 82 and 92 hermetically seals the first transducer 40 in the cavity 94. This protects the first transducer 40 during the fabrication of the second electro-acoustic transducer opposite the first transducer 40 on the second major surface 87 of the first substrate 82.

Referring now to FIGS. 12 and 13C, the second major surface 87 of the first substrate 82 is ground and polished. A gross back-grind technique is used to remove material from the second major surface 87 of the first substrate 82 and the new second major surface 87 is polished by a CMP process. The CMP process allows the polishing process to be stopped at the contact vias 80. In one example in which the depth of the contact vias is 100 μm, the nominal thickness of the first substrate 82 is approximately 100 μm following the grinding and polishing process. Thus, the contact vias 80 extend through the first substrate 82 after the back-grind and the polishing processes. The contact vias 80 thus act as a stop indicator for the back-grind and polish process, and also provide alignment targets for fabricating the second electro-acoustic transducer 50. The contact vias 80 provide electrical connections between the electrodes 42 and 46 of the first electro-acoustic transducer 40 sealed in the cavity 94 and contact pads 48c and 48d that will later be fabricated on the second major surface 87 of the first substrate 82.

After the back grind and polishing process, the second electro-acoustic transducer 50 is fabricated on the second major surface 87 of the first substrate 82 opposite the first electro-acoustic transducer 40. The process for fabricating the second electro-acoustic transducer 50 is similar to the process of fabricating the first electro-acoustic transducer 40 and will not be described in detail again here.

Referring now to FIGS. 12 and 13D, after fabrication of the second electro-acoustic transducer 50, a thick layer of electrically-conducting material is added on top of the top electrode 56 to minimize series resistance. The electrically-conducting material is gold (Au), for example, deposited using a lift-off process, for example. The thick, electrically-conducting layer is shown as part of the top electrode 56 in the Figures. The top electrode 56 and the bottom electrode 52 are typically equal in overall thickness. The lateral dimensions of the second electro-acoustic transducer 50 depend on the application. Typically, the lateral dimensions of the second electro-acoustic transducer 50 are the same as those of the electro-acoustic first transducer 40.

A layer of a dielectric material such as SiO₂ is deposited and etched to define a step insulator 57. The step insulator 57 covers part of the piezoelectric layer 54 and the bottom electrode 52 of the second electro-acoustic transducer 50. A layer of a suitable electrically-conducting material such as gold (Au) is then deposited with a typical thickness of a few micrometers; for example, 1 μm to 3 μm. The layer is etched to define the contact pads 48a and 48b and the contact pads 59a and 59b. Parts of the contact pads 48a and 48b make electrical contact with the contact vias 80a and 80b, respectively. The contact pads 48a and 48b and the contact vias 80c and 80d provide electrical connections to the top electrode 46 and the bottom electrode 42, respectively, of the first electro-acoustic transducer 40 enclosed within the cavity 94. Part of the contact pad 59a extends over the step insulator 57 into electrical contact with the top electrode 56 of the second transducer 50. Parts of the contact pads 59b make electrical contact with the bottom electrode 52 of the second transducer 50. Overlap between the contact pad 59a and the second transducer 50 is minimized to minimize the effect of the additional mass of the overlapping portion of the contact pad 59a on the resonant characteristics of the second transducer 50, the piezoelectric isolating transformer 20, or both.

Referring additionally to FIG. 1A, the contact pads 48a and 48b provide the AC input terminals 13 that supply the input AC power IAC to the electrodes 46 and 42, respectively, of the first electro-acoustic transducer 40. The contact pads 59a and 59b provide the AC output terminals 15 that receive the output AC power OAC from the electrodes 56 and 52, respectively, of the second electro-acoustic transducer 50.

Although specific embodiments of the invention are described and illustrated above, the invention is not to be limited to the specific forms or arrangements of parts so described and illustrated. For example, differing configurations, sizes, or materials may be used but still fall within the scope of the invention. The invention is defined by the claims that follow.

We claim:

1. A piezoelectric isolating transformer characterized by an operating frequency range, the piezoelectric isolating transformer comprising a resonant structure having at least one mechanical resonance in the operating frequency range, said resonant structure comprising:
an insulating substrate having a first major surface and a second major surface opposite said first major surface; and
a first electro-acoustic transducer and a second electro-acoustic transducer mechanically coupled to said first major surface and said second major surface, respectively, of said substrate, one of said electro-acoustic transducers operable to convert an input electrical power in said operating frequency range to acoustic energy that excites mechanical vibration in said resonant structure, the other of said electro-acoustic transducers converting said mechanical vibration to output electrical power.

2. The isolating transformer of claim 1, in which said first electro-acoustic transducer comprises a thin-film electro-acoustic transducer.

3. The isolating transformer of claim 1, in which said first electro-acoustic transducer comprises a bottom electrode, a top electrode and a piezoelectric layer between said electrodes.

4. The isolating transformer of claim 1, in which:
said insulating substrate comprises a first substrate and a second substrate;
said first electro-acoustic transducer is located on said first substrate;
said second electro-acoustic transducer is located on said second substrate; and
said first substrate and said second substrate are bonded together with said first electro-acoustic transducer opposite said second electro-acoustic transducer.

5. The isolating transformer of claim 1, in which:
said isolating transformer additionally comprises an additional substrate bonded to said insulating substrate, said additional substrate defining a cavity; and
said first electro-acoustic transducer is located within said cavity.

6. The isolating transformer of claim 5, in which said piezoelectric isolating transformer additionally comprises a via extending through said insulating substrate and electrically connected to said first electro-acoustic transducer.

7. The isolating transformer of claim 6, additionally comprising contact pads outside said cavity, said contact pads electrically connected by said via to said first electro-acoustic transducer.

8. The isolating transformer of claim 1, in which said output electrical power and said input electrical power are characterized by respective voltages having a ratio dependent on a relationship between the frequency of said input electrical power and the frequency of said at least one mechanical resonance.

9. A DC-to-DC converter, comprising:
an oscillator;
a rectifier; and
a piezoelectric isolating transformer comprising an input electrically connected to said oscillator, and an output electrically connected to said rectifier.

10. The DC-to-DC converter of claim 9, in which:
said piezoelectric isolating transformer is characterized by an operating frequency range and comprises a resonant structure having at least one mechanical resonance in said operating frequency range;
said oscillator generates input electrical power at a frequency in said operating frequency range; and
said resonant structure comprises:
an insulating substrate having a first major surface and a second major surface opposite said first major surface;
a first electro-acoustic transducer electrically connected to said input and mechanically coupled to said first major surface of said substrate, said first transducer converting said input electrical power to acoustic energy that excites mechanical vibration in said resonant structure; and
a second electro-acoustic transducer electrically connected to said rectifier and mechanically coupled to said second major surface of said substrate opposite said first electro-acoustic transducer, said second electro-acoustic transducer converting said mechanical vibration to output electrical power for rectification by said rectifier.

11. The DC-to-DC converter of claim 10, in which said first electro-acoustic transducer comprises a thin-film transducer.

12. The DC-to-DC converter of claim 10, in which said electro-acoustic first transducer comprises a bottom electrode, a top electrode, and a piezoelectric layer between said electrodes.

13. The DC-to-DC converter of claim 9, in which:
said piezoelectric isolating transformer additionally comprises an additional substrate bonded to said insulating substrate, said additional substrate defining a cavity; and
said first electro-acoustic transducer is located within said cavity.

14. The DC-to-DC converter of claim 9, in which said rectifier comprises a bridge rectifier.

15. The DC-to-DC converter of claim 9, in which:
said oscillator comprises a frequency control input; and
the DC-to-DC converter additionally comprises a feedback loop connected between said rectifier and said frequency control input of said oscillator, said feedback loop comprising an additional piezoelectric isolating transformer.

16. The DC-to-DC converter of claim 15, in which:
said additional piezoelectric isolating transformer comprises an input and an output; and
said feedback loop comprises:
a modulator electrically connected to receive a DC signal from said rectifier and an AC carrier signal from said output of said piezoelectric isolating transformer, said modulator having an output electrically connected to said input of said additional piezoelectric isolating transformer, and
a demodulator electrically connected to said output of said additional piezoelectric isolating transformer, said demodulator having an output, and
a comparator having inputs connected to a reference and said output of said demodulator and additionally having an output connected to said frequency control input of said oscillator.

17. The DC-to-DC converter of claim 16, in which:
said additional piezoelectric isolating transformer has a forward transmission coefficient dependent on the frequency of said AC carrier signal; and
said modulator modulates said AC carrier signal in response to said DC signal to generate a modulated carrier signal having modulation properties independent of said forward transmission coefficient of said additional piezoelectric isolating transformer.

18. The DC-to-DC converter of claim 15, additionally comprising a substrate common to said piezoelectric isolating transformer and said additional piezoelectric isolating transformer.

19. The DC-to-DC converter of claim 15, in which:
said second electro-acoustic transducer comprises a first sub-transducer and a second sub-transducer electrically connected in series to provide anti-phase voltages.

20. A fabrication method, comprising:
providing an insulating substrate having a first major surface and a second major surface opposite said first major surface;
forming a first electro-acoustic transducer on said first major surface of said substrate; and
forming a second electro-acoustic transducer on said second major surface of said substrate opposite said first electro-acoustic transducer.

21. The method of claim 20, in which said first electro-acoustic transducer comprises a thin-film electro-acoustic transducer.

22. The method of claim 20, in which said insulating substrate comprises:
an at least partially-conducting substrate; and
a layer of insulating material between said first and second transducers.

23. The method of claim 20, in which:
said method additionally comprises providing a first substrate and a second substrate each having a first major surface and a second major surface opposite said first major surface;
said forming said first electro-acoustic transducer comprises forming said first electro-acoustic transducer on said first major surface of said first substrate;
said forming said second electro-acoustic transducer comprises forming said second electro-acoustic transducer on said first major surface of said second substrate; and
said providing said insulating substrate comprises joining said second major surface of said first substrate and said second major surface of said second substrate with said first electro-acoustic transducer opposite said second electro-acoustic transducer.

24. The method of claim 20, in which:
the method additionally comprises:
providing an additional substrate having a first major surface and a second major surface opposite said first major surface,
forming in said additional substrate a cavity extending into said additional substrate from said first major surface thereof, and
bonding said first major surface of said insulating substrate and said first major surface of said additional substrate with said first transducer located within said cavity; and
said forming said second electro-acoustic transducer comprises forming, after said bonding, said second electro-acoustic transducer on said second major surface of said insulating substrate opposite said first electro-acoustic transducer.

25. The method of claim 24, in which
the method additionally comprises:
forming in said insulating substrate a contact via extending from said first major surface of said insulating substrate, and
fabricating contact pads in contact with said contact via; and
said forming said first electro-acoustic transducer comprises forming said first electro-acoustic transducer on said first major surface of said insulating substrate electrically connected to said contact via.

26. The method of claim 25, additionally comprising removing substrate material from said second major surface of said insulating substrate to expose said contact via at said second major surface of said insulating substrate.
